(19) United States
(12) Patent Application Publication
(10) Pub. No.: US 2005/0139256 A1
(43) Pub. Date: Jun. 30, 2005

(54) Solar cell assembly for use in an outer space environment or a non-earth environment

(76) Inventors: Charles Steven Korman, Schenectady, NY (US); Marc Schaepkens, Ballston Lake, NY (US); Bastiaan Arie Korevaar, Clifton Park, NY (US)

Correspondence Address: CANTOR COLBURN, LLP, 55 GRIFFIN ROAD SOUTH, BLOOMFIELD, CT, 06002, US

(21) Appl. No.: 10/750,114

(22) Filed: Dec. 31, 2003

(51) Int. Cl. H01L 31/00

(52) U.S. Cl. 136/256; 136/252; 136/259; 136/246

(57) ABSTRACT

A solar cell assembly for use in an outer space environment or a non-Earth environment and a method for controlling a temperature of the solar cell assembly are provided. The solar cell assembly includes a photovoltaic conversion layer configured to produce an electrical current when receiving photons on a first side of the photovoltaic conversion layer. The solar cell assembly further includes a thermally conductive layer thermally coupled to a second side of the photovoltaic conversion layer. Finally, the solar cell assembly includes a heat radiating layer coupled to the thermally conductive layer to radiate heat energy from the photovoltaic conversion layer.

### BACKGROUND

Solar cell panels have been used to generate electricity from sunlight. Further, solar cells and solar cell panels comprising a plurality of solar cells have been used in Earth and non-Earth applications when access to other electrical power sources is limited.

In particular, space satellites, spacecraft, and other devices used in non-Earth applications have utilized solar cell panels to provide power from sunlight for powering devices, such telecommunication devices. For purposes of discussion, the term “outer space” means space outside of the Earth's atmosphere. Further, the term “non-Earth application” means any device or system that is designed to function in outer space or on an extraterrestrial body such as a moon or a planet.

Photons that contact the solar cell panels directly generate electrical energy, wherein other photons only generate heat energy that remains unused. A problem associated with solar cell panels used in a non-Earth environment is that the panels often reach temperatures in excess of a desired operating temperature that decreases the electrical conversion efficiency of the solar cell panels. This occurs in part, because in space there is no atmosphere to allow thermal convection to cool the solar cell panels and to protect the solar cell panels from undesirable radiation in space.

Accordingly, it is desirable to provide a solar cell assembly that can be utilized in a space environment or a non-Earth environment wherein excess heat energy is capable of being radiated away from the solar cell assembly in order to maintain a temperature of the solar cell assembly within an optimal temperature operating range.

### SUMMARY

A solar cell assembly for use in an outer space environment or a non-Earth environment is provided. The solar cell assembly includes a photovoltaic conversion layer configured to produce an electrical current when receiving photons on a first side of the photovoltaic conversion layer. The solar cell assembly further includes a thermally conductive layer thermally coupled to a second side of the photovoltaic conversion layer. Finally, the solar cell assembly includes a heat radiating layer coupled to the thermally conductive layer to radiate heat energy from the photovoltaic conversion layer.

A method for controlling a temperature of a solar cell assembly used in an outer space environment or a non-Earth environment is provided. The assembly includes a first side and a second side opposite the first side. The method includes receiving a plurality of photons on the first side of the solar cell assembly. The method further includes converting energy from a first portion of the plurality of photons into electrical energy. Finally, the method includes radiating heat energy from the second side of the solar cell assembly using a radiating layer thermally coupled to the second side.

Other systems and/or methods according to the embodiments will be or become apparent to one with skill in the art upon review of the following drawings and detailed description. It is intended that at all such additional systems and methods be within the scope of the present invention, and be protected by the accompanying claims.

### BRIEF DESCRIPTION OF THE DRAWINGS

FIG. 1 illustrates a space satellite having solar cell panels;

FIG. 2 is a top plan view of a solar cell array having a plurality of solar cell assemblies;

FIG. 3 is an enlarged portion of a solar cell assembly of the solar cell array of FIG. 2;

FIG. 4 is another enlarged portion of a solar cell assembly of the solar cell array of FIG. 2;

FIG. 5 is a cross-sectional view of a portion of a solar cell assembly constructed in accordance with an exemplary embodiment of the present invention;

FIG. 6 is a view illustrating layers of a solar cell assembly constructed in accordance with an exemplary embodiment of the present invention;

FIG. 7 is a cross-sectional view of a portion of a solar cell assembly constructed in accordance with another exemplary embodiment of the present invention;

FIG. 8 is a cross-sectional view of a portion of a solar cell assembly constructed in accordance with still another exemplary embodiment of the present invention;

FIG. 9 is a bottom view of the solar cell array of FIG. 2;

FIG. 10 is a flowchart illustrating portions of a method for manufacturing solar cell assemblies in accordance with exemplary embodiments of the present invention;

FIG. 11 is an illustration of an expanding thermal plasma deposition system used for manufacturing exemplary embodiments of the present invention;

FIG. 12 is a graph illustrating the operating efficiency of a solar cell assembly versus a temperature of the solar cell assembly; and

FIG. 13 is a graph illustrating the temperature of a solar cell assembly versus the thickness of an emissivity layer in the solar cell assembly.

### DETAILED DESCRIPTION

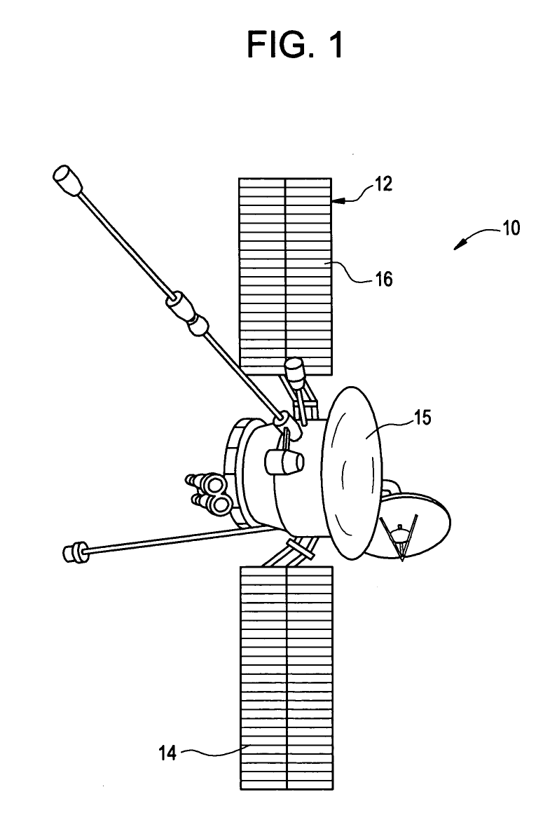

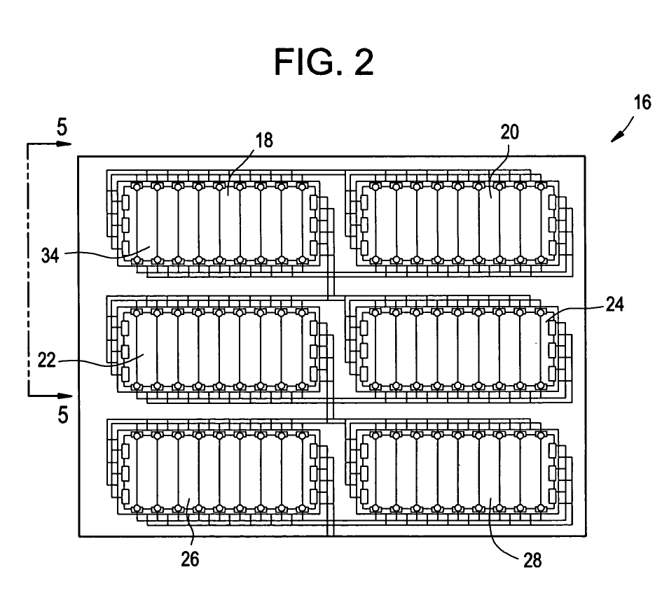

Referring generally to FIG. 1, a telecommunications satellite 10 is illustrated. Satellite 10 is provided to illustrate just one possible use of exemplary embodiments of the present invention. Satellite 10 is designed for use in non-Earth applications such as being placed in orbit around Earth for use in applications known to those skilled in the art of satellites and spacecraft. In order to provide power to the satellite, solar panels 12 and 14 are provided and positioned to face the sun in order to generate, store and use power. In accordance with an exemplary embodiment of the present invention, the solar cells and/or solar cell panels comprising a plurality of solar cells for use in any non-Earth application are constructed in accordance with the teachings disclosed herein. In particular, each of the solar panels includes a solar cell array 16, shown in FIG. 2, for powering the satellite. It should be noted that solar panels 12 and 14 could be utilized with any device or system (e.g., spacecraft, space lab) in a non-Earth environment for generating electricity to power the device or system.

Referring now to FIG. 2, each solar cell array 16 includes a plurality of solar cell assemblies electrically coupled together. The number of solar cell assemblies is not intended to be limited, the number and configuration of which will depend on the intended application. For exemplary purposes, solar cell assemblies 18, 20, 22, 24, 26, and 28 are illustrated. The design of the various solar cell assemblies are substantially the same and electrically coupled to one another in a similar manner.

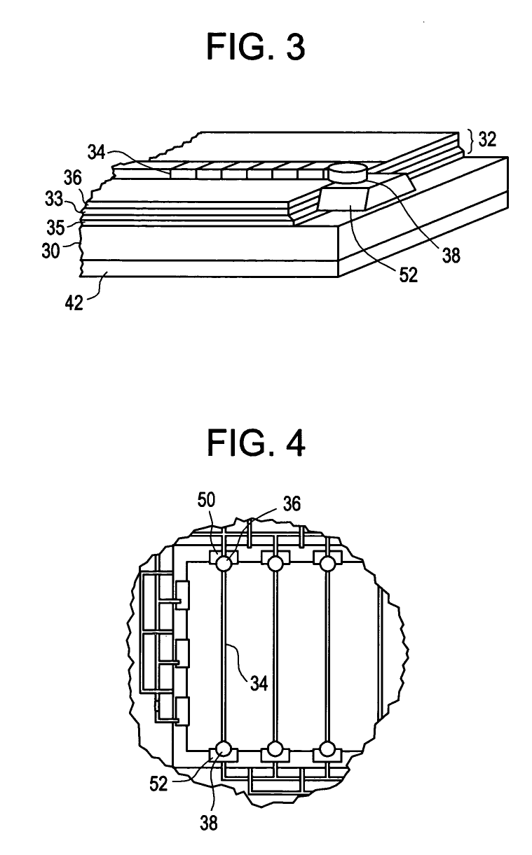

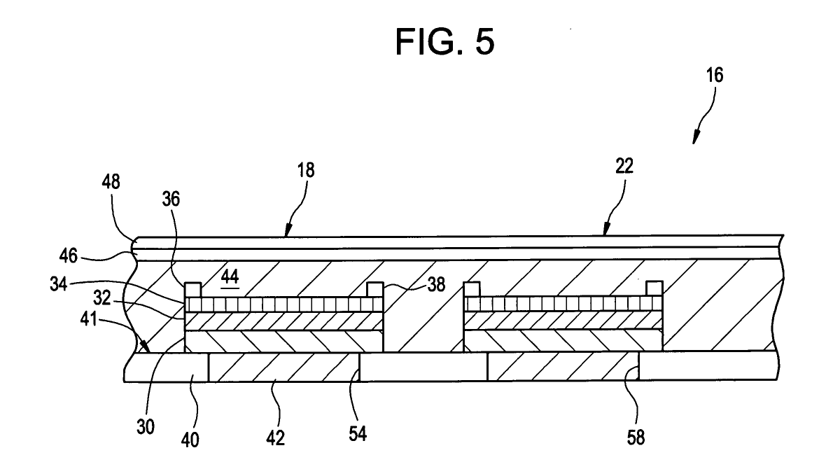

Referring to FIGS. 3-5, a solar cell assembly is illustrated. Each solar cell assembly, (e.g., 18, 20, 22, 24, 26, and 28) in the array 16 generally includes a stainless steel substrate 30, a solar cell 32 including a photovoltaic conversion, an internal grid line 34, electrical contacts 36, 38, a flexible substrate 40, a heat radiating layer 42, an emissivity layer 44, a transparent electrically conductive layer 46, a self-cleaning layer 48, and isolation barriers 50, 52. It should be noted that each of the foregoing components that form the solar cell assembly are configured to be substantially flexible as well as being capable of holding a particular configuration after being manipulated or bent. This is particularly useful for space or non-Earth applications wherein the solar cell array is constructed, manipulated into a smaller configuration for storage during transportation into space and then un-furled into a deployed state or configuration for generating power once the solar cell assembly is deployed into space. For example, solar cell assembly 18 can be configured to be rolled-up or manipulated into a smaller configuration (e.g., cylindrical roll or other configuration having a diameter or outer configuration of about 1 inch inner or greater). The aforementioned dimensions are merely provided as examples and are not intended to limit the scope of the present invention. Accordingly, solar cell assembly 18 is configured to be flexibly manipulated, and hold its manipulated shape or an unfurled shape (e.g., rolled and un-rolled).

As shown, stainless steel substrate 30 is disposed over an aperture 54 extending through substrate 40. In particular, an area of stainless steel substrate 30 can be greater than an area of aperture 54 so that the stainless steel substrate 30 can be fixedly attached to a surface 41 of substrate 40 over aperture 54. Stainless steel substrate 30 can be fixedly attached to surface 41 using a high-temperature glue, for example. Further, stainless steel substrate 30 can have a thickness of about 5 millimeters (mm) so as to provide considerable flexibility therein. Substrate 30 could be constructed with a thickness less than or greater than about 5 mm depending upon a desired flexibility or a desired thermal conductivity of stainless steel substrate 30. The particular configurations illustrated in FIGS. 3-5 are provided as examples and the present invention is not intended to be limited to the specific configurations illustrated in the Figures.

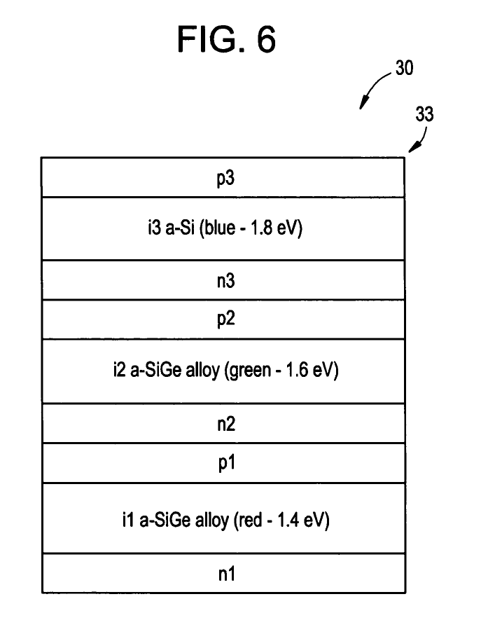

The solar cell 32 is provided to generate an electrical current in response to photons contacting solar cell 32. Solar cell 32 is fixedly attached to stainless steel substrate 30. As shown more clearly in FIG. 3, solar cell 32 includes a photovoltaic conversion layer 33, an electrical contact layer 36 constructed from indium tin oxide on an upper surface of layer 33, and an electrical contact reflector layer 33 constructed from silver or zinc oxide on a bottom surface of layer 33. Electrical contact layer 36 is electrically coupled to contact 38 disposed on an isolation barrier 52. When photons contact photovoltaic conversion layer 33 a voltage potential is created between layers 33, 35. Referring to FIG. 6, photovoltaic conversion layer 33 can comprise a plurality of sub-layers. In particular, photovoltaic conversion layer 33 may comprise: (i) a p3 sub-layer comprising a P-type semiconductor sub-layer, (ii) an i3 sub-layer comprising an intrinsic semi-conductor sub-layer, (iii) an n3 sub-layer comprising a N-type semiconductor sub-layer, (iv) a p2 sub-layer comprising a P-type semiconductor sub-layer, (v) an i2 sub-layer comprising an intrinsic semiconductor sub-layer, (vi) an n2 sub-layer comprising a N-type semiconductor sub-layer, (vii) a p1 sub-layer comprising a P-type semiconductor sub-layer, (viii) an i1 sub-layer comprising an intrinsic semi conductor sub-layer, and a (ix) an n1 sub-layer comprising a N-type semiconductor sub-layer.

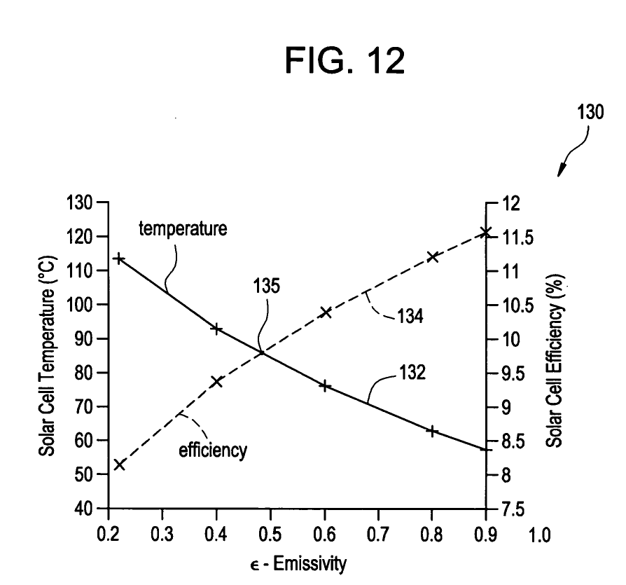

Referring to FIG. 12, a graph illustrating an operating efficiency of a solar cell 32 versus a temperature of the solar cell is illustrated. In particular, line 134 represents the efficiency of solar cell 32 and a line 132 represents the temperature of solar cell 32. The intersection point 135 of line 132 and line 134 represents one desired operating temperature for solar cell 32. As shown, the desired temperature is approximately 85° C. in this embodiment. Accordingly, solar cell 32 can most efficiently produce electricity when solar cell 32 has an internal temperature range between 50° C. and 110° C. Further, both emissivity layer 44 and heat radiating layer 42 are utilized for maintaining a temperature of solar cell 32 within a desired temperature range.

Referring to FIGS. 2 and 4, grid line 34 is provided to collect and conduct electrons flowing through solar cell 32. As shown grid line 34 is disposed on solar cell 32 and is electrically coupled to contacts 36, 38. Grid line 34 can be constructed from silver (Ag) or aluminum (Al). It should be noted that although only one grid line is shown in FIG. 4, solar cell assembly 18 includes: (i) a plurality of upper grid lines collecting and conducting electrons flowing proximate an upper side of solar cell 32, and (ii) a plurality of lower grid lines collecting and conducting electrons flowing proximate a lower side of solar cell 32, as shown in FIG. 2. Grid line 34 is configured to be substantially flexible.

Referring to FIG. 4, emissivity layer 44 is provided to absorb a portion of energy of photons contacting layer 44 and to radiate the absorbed energy away from solar cell 32. By radiating the absorbed energy, solar cell 32 can be maintained within an optimal temperature range. In particular, emissivity layer 44 is configured to absorb the energy from light wavelengths greater than or equal to 5 microns and to radiate the absorbed heat energy away from solar cell 32. It should be noted that light wavelengths greater then or equal to 5 microns lack sufficient energy to break free “electron-hole” pairs in solar cell 32 to create an electrical current. Thus, any light wavelengths greater than or equal to 5 microns contacting solar cell 32 merely generate heat within solar cell 32. Thus, emissivity layer 44 is provided to absorb and radiate the energy from light wavelengths in this undesirable wavelength range and to allow light wavelengths less than 5 microns (e.g., wavelengths between 2-800 nm) to contact solar cell 32 to generate electricity.

Emissivity layer 44 can have an emissivity greater than or equal to 0.8. The term “emissivity” means the relative power of a surface to emit heat by radiation, and in particular, the ratio of the radiant energy emitted by a surface to that emitted by a black body having the same area and temperature. Emissivity layer 44 can be constructed from silicon oxides such as SiO₂, silicon nitrides such as Si₃N₄, silicon oxynitrides, silicon oxycarbides, silicon carbides, silicon nitrocarbides, silicon oxynitrocarbides, and the like. Further, emissivity layer 44 can have a thickness of 10 microns or greater and may be disposed over substantially an entire top surface of solar cell array 16. An example of a suitable emissivity layer and a method of making the emissivity layer is found in International Application WO 01/75486 A2.

It should be noted that as space satellites orbit the Earth, the satellites come into contact with electrons floating through space. In particular, solar panel assemblies, e.g., 18, 20, 22, 24, 26, and 28, on the satellites come into contact with the electrons that adhere to an outer surface of the solar panel assemblies. After a significant amount of electrons adhere to the solar panel assemblies, an electro-static discharge can occur through solar cells in the solar panel assemblies that can damage the solar cells therein.

The transparent electrically conductive layer 46 is provided to capture electrons that are traveling in space that contact the solar panel assemblies. The transparent electrically conductive layer 46 conducts the electrons away from the solar cell 32 to prevent electro-static discharge therein. Conductive layer 46 can be constructed from indium tin oxide (ITO) or zinc oxide. Conductive layer 46 is preferably disposed over emissivity layer 44 at a thickness of about 30 to about 100 nanometers (nm) and may be disposed over substantially the entire top surface of the solar cell array 16. Conductive layer 46 also reflects light wavelengths greater than or equal to 5 microns contacting layer 46 away from solar cell 32. Layer 46 is configured to be substantially flexible.

In the illustrated embodiment, self-cleaning layer 48 is provided to remove dust or dirt that can adhere to solar cell array 16 when satellite 10 is at a relatively low Earth orbit. Self-cleaning layer 48 can be disposed over layer 46 and may comprise a layer of titanium dioxide (TiO₂) that is substantially flexible. While not wanting to be bound by theory, it is believed that the self-cleaning layer 48 attracts water particles, such as may be present at low Earth orbits, which then moves underneath any dust or dirt contacting layer 48 so that the dust or dirt will no longer bond to layer 48. Thereafter, as satellite 10 moves through space, the dust and dirt floats off of layer 48. It should be noted that in an alternate embodiment of assembly 18 (not shown), self-cleaning layer 48 could be removed from the assembly.

It should be noted that on known solar cell assemblies, the solar cell assemblies are mounted on a rigid frame for holding the various components of the assemblies. Thus, the solar cell assemblies are not flexible. Further, the rigid frames are relatively heavy which results in relatively high costs to transport the solar cell assemblies from Earth to an outer space environment or a non-Earth environment. Further, because the solar cell assemblies cannot be rolled-up, a relatively large transport vehicle (e.g., rocket) having a large cargo area must be utilized to transport the known solar cell assemblies from Earth to an outer space environment or a non-Earth environment.

Referring to FIGS. 2, 4, and 8, flexible substrate 40 is provided to support solar cell assemblies 18, 20, 22, 24, 26, 28 and is configured to be rolled-up for transport into a space environment or a non-Earth environment. As shown, substrate 40 includes apertures 54, 56, 58, 60, 62, 64 extending therethrough. Further, solar cell assemblies 18, 20, 22, 24, 26, 28 are disposed on one side of substrate 40 over apertures 54, 56, 58, 60, 62, 64, respectively. As shown, a periphery of each of solar cell assemblies 18, 20, 22, 24, 26, 28 is larger than a periphery of each of apertures 54, 56, 58, 60, 62, 64 respectively. Solar cell assemblies 18, 20, 22, 24, 26, 28 include radiating layers 42, 72, 74, 76, 78, 80 extending through apertures 54, 56, 58, 60, 62, 64, respectively, to conduct heat energy away from the assemblies.

Flexible substrate 40 can be constructed from a thermally non-conductive polyimide identified by the trademark “KAPTON H” or the trademark “KAPTON E”, manufactured by DuPont Corporation. Because the KAPTON® product is a thermally non-conductive polyimide, the inventors herein have recognized that the heat radiating layers can be disposed through the KAPTON® layer 40 to radiate excess heat generated in solar cell 32 (and the other solar cells in solar cell array 16) from a backside of solar cell array 16.

In alternate embodiments, substrate 40 can be constructed from films of one or more of the following materials: (i) polyethyleneterephthalate (“PET”), (ii) polyacrylates, (iii) polycarbonate, (iv) silicone, (v) epoxy resins, (vi) silicone-functionalized epoxy resins, (vii) polyester such as polyester identified by the trademark “MYLAR” manufactured by E.I. du Pont de Nemours & Co., (viii) a material identified by the trademark “APICAL AV” manufactured by Kanegaftigi Chemical Industry Company, (ix) a material identified by the trademark “UPILEX” manufactured by UBE Industries, Ltd.; (x) polyethersulfones “PES,” manufactured by Sumitomo, (xi) a polyetherimide identified by the trademark “ULTEM” manufactured by General Electric Company, and (xii) polyethylenenaphthalene (“PEN”).

In other alternate embodiments, substrate 40 can be constructed from stainless steel. The stainless steel may have an insulating coating or may not have an insulating coating depending upon desired thermal characteristics of substrate 40. Alternately, flexible substrate 40 can be constructed from a relatively thin glass that is reinforced with a polymeric coating, such as a glass manufactured by Schott Corporation, for example.

Referring to FIG. 4, heat-radiating layer 42 is provided to radiate excess heat away from solar cell 32 to maintain an optimal operating temperature range of solar cell 32. As shown, layer 42 is operably coupled to stainless steel substrate 30. Because substrate 30 is thermally conductive, excess heat energy from solar cell 32 is conducted through stainless steel layer 32 to heat radiating layer 42. Thereafter, heat-radiating layer 40 to radiates the excess heat energy into space. Heat radiating layer 42 can comprise a black body radiating layer. In particular, layer 42 can comprise a layer of chromium oxide applied through aperture 54 to a bottom surface of stainless steel substrate 30. As shown, heat- radiating layer 42 may have a thickness substantially equal to the thickness of flexible substrate 40. In an alternate embodiment, a second stainless steel substrate (not shown) could be fixedly attached between substrate 30 and heat radiating layer 42.

The isolation barriers 50, 52 are provided to electrically isolate contacts 36, 38, respectively, in assembly 18. It should be noted that solar cell assembly 18 includes a plurality of such isolation barriers. In particular, each electrical contact proximate an upper surface of solar cell assembly 18 is coupled to a corresponding isolation barrier. Further, each electrical contact proximate a lower surface of solar cell assembly 18 is coupled to a corresponding isolation barrier.

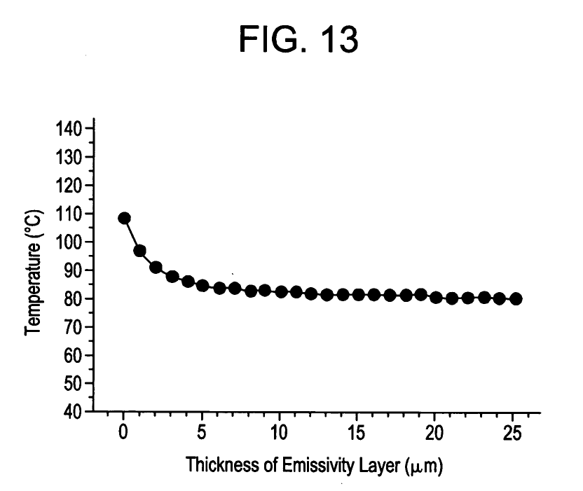

Referring to FIG. 13, a graph illustrating the operating temperature of solar cell assembly 18 is illustrated. In particular, the graph indicates that a temperature of solar cell assembly 18 can be maintained between about 80° C. and about 90° C. when utilizing emissivity layer 44 of at least 10 microns in thickness and heat radiating layer 42. It should be noted that a temperature of solar cell assembly 18 could be maintained at a range less than or greater than 80° C.-90° C. depending on the desired operating characteristics of assembly 18.

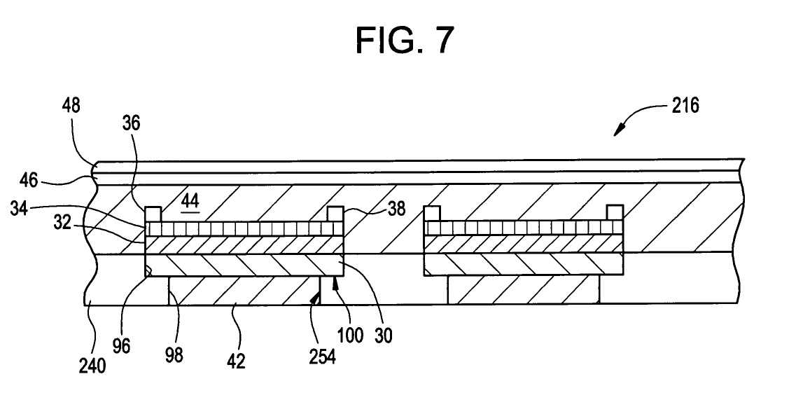

Referring to FIG. 7, another exemplary embodiment of a solar cell array (e.g. solar cell array 216) is illustrated. The primary difference between solar cell array 216 and solar cell array 16 is that solar cell array 216 has an annular recess about the aperture in flexible substrate that is configured to receive the stainless steel substrate, whereas solar cell array 16 has a stainless steel substrate that rests on top of an aperture in the flexible substrate.

As shown, flexible substrate 240 has an aperture 254 including aperture portions 96, 98. Aperture portion 96 is configured to receive at least a portion of stainless steel substrate 30. Aperture portion 96 has a periphery smaller than stainless steel substrate 30 such that substrate 30 rests on a ledge 100 defined by aperture portions 96, 98. Aperture portion 96 is configured to receive heat radiating layer 42.

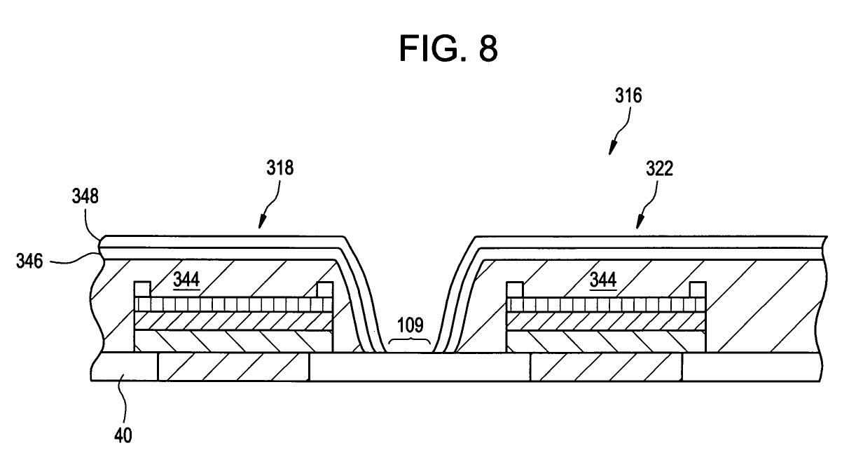

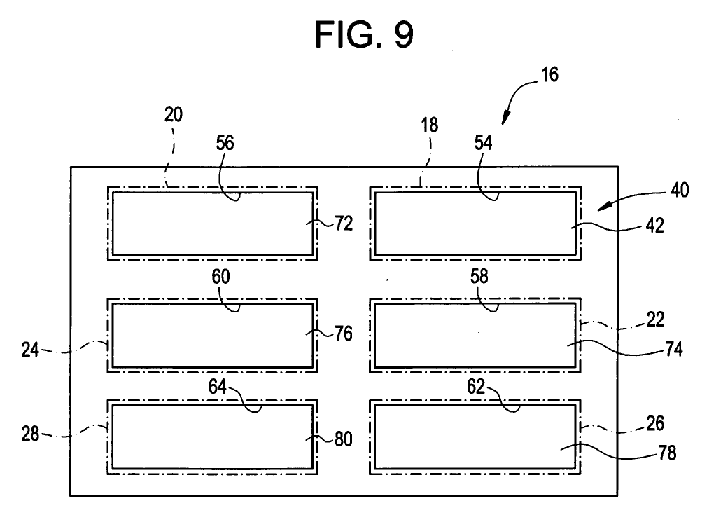

Referring to FIG. 8, another exemplary embodiment of a solar cell array (e.g. solar cell array 316) is illustrated. The primary difference between solar cell array 316 and solar cell array 16 is that solar cell array 316 has emissivity layer 344, a transparent conductive layer 346, and a self-cleaning layer 348 that does not cover the entire top surface of solar cell array 316. Whereas solar cell array 16 has an emissivity layer 44, a conductive layer 46, and a self-cleaning layer 48 that covers substantially the entire top surface of solar cell array 16.

As shown, solar cell array 316 has an emissivity layer 344, a conductive layer 346, and a self-cleaning layer 348 that covers the solar cell assemblies (e.g., solar cell assemblies 318 and 322) but leaves a portion of flexible substrate 40 uncovered. As shown, flexible substrate 40 has a region 109 between solar cell assemblies 318, 322 that is not covered by layers 344, 346, 348.

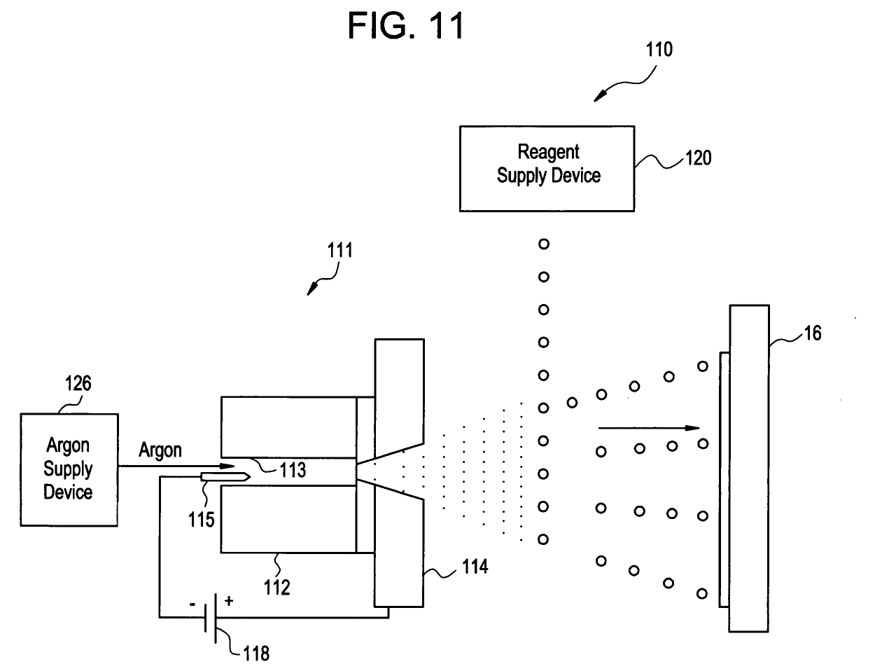

Referring to FIG. 11, before providing a detailed description of how a solar cell array can be made, a brief description of an expanding thermal plasma deposition system 110 that can be utilized to apply layers 44, 46, 48 to a solar cell will be explained. System 110 includes a plasma ejection device 111, a reagent supply device 120, and an argon supply device 126.

Plasma ejection device 111 includes a body portion 112, a nozzle portion 114, a cathode member 115, and a voltage supply 118. An aperture 113 extends through body portion 112 and nozzle portion 114. Aperture 113 is provided to allow an argon gas from argon supply device 126 to be communicated therethrough. Cathode member 115 is disposed in aperture 113.

Voltage source 118 is electrically connected between cathode member 115 and nozzle portion 114. When argon supply device 126 supplies argon gas through aperture 113, the argon gas is electrically charged by cathode member 115.

Reagent supply device 120 is provided to supply reagent compound particles that will be subsequently coated on a portion of solar array 16. For example, reagent supply device 120 could supply one or more of: (i) silicon oxides, (ii) silicon nitrides, (iii) silicon oxynitrides, (iv) silicon oxycarbides, (v) silicon carbides, (vi) silicon nitrocarbides, (vii) silicon oxynitrocarbides—that can be used by system 110 to form emissivity layer 44 on a solar cell. Further, for example, reagent supply device 120 could supply indium tin oxide (ITO) or zinc oxide that can be used by system 110 to form transparent electrically conductive layer 46 on a solar cell. Further, for example, reagent supply device 120 could supply titanium dioxide to form self-cleaning layer 48 on a solar cell.

During operation of system 110 when plasma ejection device 111 is disbursing ionized argon particles and reagent supply device 120 is supplying reagent particles, the ionized argon particles attach to the reagent particles and the combined particles are directed toward a surface of solar cell array 16. As the argon particles and reagent particles contact the surface solar cell array 16, the reagent particles adhere to the surface of solar cell array 16. It should be noted that system 110 has a relatively fast rate of applying a desired layer or layers to a solar cell assembly. For example, system 110 can deposit layers at greater than 1 micrometer/minute with a deposition temperature of less than 200 degrees Celsius.

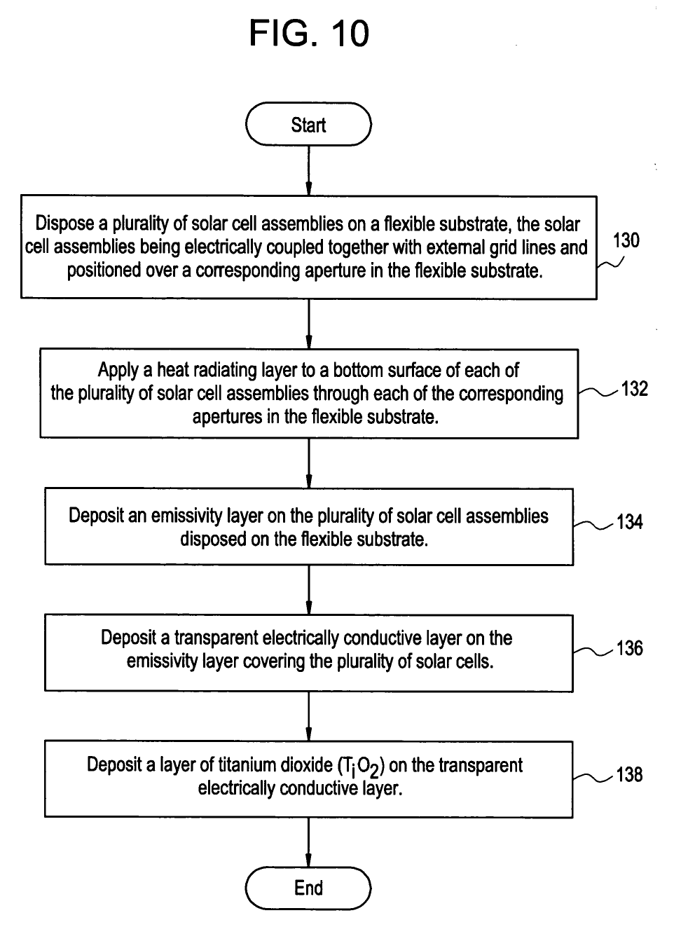

Referring to FIG. 10, a method for making a solar cell array will now be described. It should be noted that the method for making the solar cell array is directed to adding the following layers: (i) emissivity layer 44, (ii) transparent electrically conductive layer 46, (iii) self-cleaning layer 48, and (iv) heat radiating layer 42—to a plurality of solar cell assemblies each including a stainless steel substrate, a solar cell, grid lines, and electrical contacts.

At step 130, a plurality of solar cell assemblies are disposed on flexible substrate 40. The solar cell assemblies are electrically coupled together with external grid lines and positioned over corresponding apertures in flexible substrate 40.

At step 132, a heat radiating layer is applied to a bottom surface of each of the plurality of solar cell assemblies through each of the corresponding apertures in flexible substrate 40.

At step 134, an emissivity layer 44 is deposited on the plurality of solar cell assemblies disposed on flexible substrate 40. Emissivity layer 44 can be deposited on the plurality of solar cell assemblies utilizing thermal plasma deposition system 110 or a sputtering system known to those skilled in the art.

At step 136, transparent electrically conductive layer 46 is deposited on emissivity layer 44. Conductive layer 44 can be deposited on the plurality of solar cell assemblies utilizing thermal plasma deposition system 110 or a sputtering system known to those skilled in the art.

At step 138, self-cleaning layer 48 can be deposited on conductive layer 46. Self-cleaning layer 48 can be deposited on the plurality of solar cell assemblies utilizing thermal plasma deposition system 110 or a sputtering system known to those skilled in the art.

The solar cell assemblies and a method for controlling a temperature of the solar cell assemblies described herein represent a substantial advantage over known solar cell assemblies and methods. In particular, the solar cell assemblies are configured to radiate excess heat energy from the solar cell assemblies from the backside of the assemblies. Accordingly, an operating temperature of the solar cell assembly can be maintained within an optimal operating temperature range in a space environment or in a non-Earth environment.

While the invention is described with reference to an exemplary embodiment, it will be understood by those skilled in the art that various changes may be made an equivalence may be substituted for elements thereof without departing from the scope of the invention. In addition, many modifications may be made to the teachings of the invention to adapt to a particular situation without departing from the scope thereof. Therefore, is intended that the invention not be limited the embodiment disclosed for carrying out this invention, but that the invention includes all embodiments falling with the scope of the intended claims. Moreover, the use of the term's first, second, etc. does not denote any order of importance, but rather the term's first, second, etc. are us are used to distinguish one element from another. CLAIMS

1. A solar cell assembly for use in an outer space environment or a non-Earth environment, comprising:
a photovoltaic conversion layer configured to produce an electrical current when receiving photons on a first side of said photovoltaic conversion layer;
a thermally conductive layer thermally coupled to a second side of said photovoltaic conversion layer; and, a heat radiating layer coupled to said thermally conductive layer to radiate heat energy from said photovoltaic conversion layer.

2. The solar cell assembly of claim 1, wherein said thermally conductive layer is constructed from a metal or a metal alloy.

3. The solar cell assembly of claim 2, wherein said metal comprises stainless steel.

4. The solar cell assembly of claim 1, wherein said heat radiating layer comprises a black body radiating layer.

5. The solar cell assembly of claim 4, wherein said black body radiating layer comprises a layer of chromium oxide.

6. The solar cell assembly of claim 1, wherein a temperature of said photovoltaic conversion layer is maintained below a predetermined temperature by radiating heat energy from said photovoltaic conversion layer.

7. The solar cell assembly of claim 6, wherein said predetermined temperature is 110 degrees Celsius.

8. The solar cell assembly of claim 1, further comprising:
a first layer proximate said first side of said photovoltaic conversion layer for absorbing and radiating electromagnetic radiation from said assembly to reduce a temperature of said photovoltaic conversion layer.

9. The solar cell assembly of claim 8, wherein said first layer is configured to have an emissivity level greater than or equal to 0.8.

10. The solar cell assembly of claim 8, wherein said first layer has a thickness greater than 10 microns.

11. The solar cell assembly of claim 8, wherein said first layer is constructed from a silicon compound selected from the group consisting of silicon oxides, silicon nitrides, silicon oxynitrides, silicon oxycarbides, silicon carbides, silicon nitrocarbides, silicon oxynitrocarbides, and mixtures thereof.

12. A method for controlling a temperature of a solar cell assembly used in an outer space environment or a non-Earth environment, the assembly having a first side and a second side opposite the first side, the method comprising:
receiving a plurality of photons on said first side of said solar cell assembly;
converting energy from a first portion of said plurality of photons into electrical energy; and,
radiating heat energy from said second side of the solar cell assembly using a radiating layer thermally coupled to the second side.

13. The method of claim 12, further comprising:
absorbing energy from a second portion of the plurality of photons and radiating the energy from the second portion of the plurality of photons away said first side of said solar cell assembly.

14. The method of claim 12, wherein said temperature of said solar cell assembly is maintained below a predetermined temperature.

15. The method of claim 14, wherein said predetermined temperature is 110 degrees Celsius.
